(19) United States
(12) Patent Application Publication
(10) Pub. No.: US 2022/0098969 A1
(43) Pub. Date: Mar. 31, 2022

(54) METHOD FOR DETERMINING HYDROCARBON PRODUCTION OF A RESERVOIR

(71) Applicant: TOTAL SE, Courbevoie (FR)

(72) Inventor: Pascal HENON, Pau (FR)

(21) Appl. No.: 17/427,543

(22) PCT Filed: Feb. 1, 2019
(86) PCT No.: PCT/IB2019/000151

§ 371 Date: Jul. 30, 2021

(51) Int. Cl. E21B 47/003; G01V 99/00; G06F 30/23; G06F 30/28

(52) U.S. Cl. CPC E21B 47/003; G01V 99/005; E21B 2200/20; G06F 30/28; G06F 30/23

(57) ABSTRACT

A method for determining hydrocarbon production of a reservoir includes modeling the reservoir with a gridded model having a coarse partition and a fine partition. A first matrix is determined based on a Jacobian matrix function of the gridded model. A first projector matrix is determined as a concatenation of relevant generalized eigenvectors of a first square matrix and a second square matrix derived from the first matrix. A submatrix is extracted from the first projector matrix, and a projector matrix is determined based on a concatenation of vectors derived from relevant generalized eigenvectors of a third square matrix and a fourth square matrix derived from the submatrix. A preconditioner operator is determined based on the projector matrix, and hydrocarbon production is determined for the reservoir based on the preconditioner operator.

### BACKGROUND OF THE INVENTION

The present invention relates to the determination of hydrocarbon production in reservoirs for oil/gas industry.

The approaches described in this section could be pursued, but are not necessarily approaches that have been previously conceived or pursued. Therefore, unless otherwise indicated herein, the approaches described in this section are not prior art to the claims in this application and are not admitted to be prior art by inclusion in this section. Furthermore, all embodiments are not necessarily intended to solve all or even any of the problems brought forward in this section.

For the oil/gas company, the determination of the expected production of a reservoir is a key indicator in order to determine where to drill a well and in order to assess the economic value of a reservoir.

In the prior art, dynamic simulator is used to determine the expected production.

From a mathematical point of view, the continuity equation cannot be solved with an analytical solution (in the general case).

Therefore, to solve this problem, numerical solutions are sought, by discretizing the space (i.e. gridding the space into a plurality of adjacent cells) and time (time steps). To determine the numerical solutions, many methods propose solving the following equation (combination of mass conservation equation and Darcy's Law) for each component:

$$\frac{{dM}_{k}}{dt} = - {\sum }_{i in neighbouring} {F}_{ki} - {\sum }_{w in well} {Q}_{k - w}$$

with dMₖ the mass accumulated in cell k during the current time step dt for said component, Fₖᵢ the net flow rate from cell k into the neighboring cell i during dt, and Q_{k-w} the net flow rate from cell k into well w during dt.

Although this equation has a linear expression, it is, in fact, non-linear with respect to the physical unknowns (pressure, hydrocarbon component compositions, temperatures . . . ) that are needed to compute the net flow rates. Thus at each time step, one must find the unknown values in cell k so that the non-linear residual (R_{fl})ₖ is nullified:

$${( {R}_{fl} )}_{k} = \frac{{dM}_{k}}{dt} + {\sum }_{i in neighbouring} {F}_{ki} + {\sum }_{w in well} {Q}_{k - w}$$

The method for the resolution (non-linear Newton iterations) is summarized in FIG. 1.

For a given time step, this time step is considered (step 101).

For the time step t₁ corresponding to the considered time step, the simulator chooses, a priori, a new solution X1 and starts looking at which correction Δx is needed to get the solution R(X₁+Δx)=0.

As it is often considered that Δx is small, it is possible to linearize the equation (step 102) into R(X₁)+J_{X1}Δx=0.

To solve the equation R(X₁)+J_{X1}Δx=0 (step 103), it is required to invert the Jacobian matrix J_{X1}:Δx=−J_{X1}⁻¹R(X₁).

Once Δx determined, the non-linear residual R(X₁+Δx) is determined (step 104).

If the non-linear residual R(X₁+Δx) is lower than a predetermined threshold ε (step 105), the time step is considered as solved and X1 is outputted (step 106).

Otherwise, step 102 is reiterated with X1=X1′ with X1′=X1+Δx if the maximum number of nonlinear iterations is not reached (test 107, a non-linear iteration being the iteration triggered by test 107: e.g. steps 103→104→105→107→102→103).

If the maximum number of non-linear iterations is reached, the time step may be reduced (step 108) and the non-linear iteration restarted with the reduced time step (step 101).

Due to this algorithm, it is determined that most of the computation time is spent on the step 103, i.e. inversion of the Jacobian matrix J_{X1}.

The Jacobian J_{X1} is a sparse matrix: indeed, each equation of the Jacobian only involves unknowns related to cells of the gridded model that are connected. The entries of the Jacobian matrix that are related to non-adjacent cells are 0.

The method for the resolution of the above flow problem involves an iterative computation, at each time step and for each cell of the gridded representation of the reservoir, of an equation of the type Ax=b which links the values of physical parameters involved in the flow problem in the cell to the values of these parameters in adjacent cells.

In classical reservoir simulation, the solving of equation of the type Ax=b (where A is a Jacobian matrix or a matrix derived from a Jacobian matrix, b a vector and x the solution vector to find) uses iterative methods (e.g. GMRES, generalized minimal residual method, Conjugate Gradient, BICGStab, see Y. Saad, Iterative Methods for Sparse Linear Systems (2^{nd} edition), SIAM, 2003 for details). The iterative methods classically rely on finding an approximation of the solution in a Krylov subspace such that it satisfies a Petrov-Galerkin condition (or variant of Petrov-Galerkin condition, see Y. Saad, Iterative Methods for Sparse Linear Systems (2^{nd} edition), SIAM, 2003 for more details).

The convergence of said method is function of the ratio between the greatest eigenvalue and the smallest eigenvalue of the matrix A. This ratio is called the condition number of the matrix. The larger is the condition number, the higher will be the number of iterations to solve the linear system Ax=b at a prescribed accuracy.

Instead of solving Ax=b, it is possible to use a preconditioner M⁻¹ and to solve:
M⁻¹Ax=M⁻¹b (left preconditioner providing the same solution)
AM⁻¹x′=b (right preconditioner, used after a variable change)

Using a preconditioner generally increases the convergence speed of the iterative resolution algorithm of the linear system.

The choice of the preconditioner M⁻¹ is very important; it must be chosen such that the condition number of the linear operator M⁻¹A (or AM⁻¹) is lower than the condition number of A. The ideal choice to lower the condition number is M⁻¹=A⁻¹ but of course this has no interest as a preconditioner since the problem is precisely to determine A⁻¹x. Thus a good preconditioner is a linear operator such that the condition number of the preconditioned system M⁻¹Ax=M⁻¹b (or AM⁻¹x′=b), i.e. the condition number of M⁻¹A (or AM⁻¹), is much lower than the original system Ax=b, i.e. the condition number of A, and such that applying M⁻¹ on a vector is much cheaper in number of arithmetic operations than applying directly A⁻¹. It is noticeable that a solver can play the role of preconditioner for another solver, this has to be kept in mind to avoid any confusion since many preconditioner techniques are also solver on their own (but of course when used as preconditioner the convergence tolerance is looser than when they are used as plain solver). As a direct consequence of the condition number definition, an efficient preconditioner can be constructed from the knowledge of the eigenvectors corresponding to the extremum values of the eigenvalues (for example by ensuring that M⁻¹Av=v for v an eigenvector corresponding to a large or a small eigenvalue of A, and M⁻¹Av=Av for the other eigenvalues of A). In practice, computing eigenvectors is usually much more costly in number of arithmetic operations than solving a linear system. Nevertheless, in some problems some inexpensive approximations of the eigenvalues can be computed either by using some physical knowledge of the problem from which the Jacobian system is derived or by exploiting some properties of the matrix A and an efficient preconditioner can be devised from those approximations.

In industrial reservoir simulators, the usual numerical discretization scheme is fully implicit thus each equation of the Jacobian system involves a set of unknowns. For instance, the unknowns involved in reservoir simulators may correspond to pressure, or fluid (e.g. oil, water, gas) saturation and concentration in each cell of the gridded model. In a reservoir, the fluid motion is driven by the pressure field, this fact is reflected on the fact that the conditioning of the Jacobian system is mainly dependent from the conditioning of the pressure subsystem obtained after elimination of the other types of unknowns.

According to CPR (Constrained Pressure Residual) preconditioning method, the problem can be reduced to a system that depends solely on the pressure at the preconditioner. Such method is presented for instance in J. R. Wallis, R. P. Kendall T. E. Little: “Constrained Residual Acceleration of Conjugate Residual Methods”, SPE 13563, presented at the 8th Symposium on Reservoir Simulation, Dallas, Feb. 10-13, 1985, and in Cao, H., Tchelepi, H. A., Wallis, J., Yardumian, H.: “Parallel Scalable Unstructured CPR-Type Linear solver for Reservoir simulation”, SPE 96809, Proceedings of the SPE Annual Technical Conference, Dallas, Oct. 9-12, 2005. The CPR method is based on this property: a Jacobian preconditioner is built as a multistep preconditioner which main operation consists in preconditioning an approximation of the reduced pressure linear system. It is noticeable that other numerical schemes such as IMPES (IMplicit Pressure Explicit Saturation) can lead directly to a Jacobian system where there are only pressure unknowns in the Jacobian system. The method of preconditioning that we present in this document is not dependent from the fully implicit numerical scheme nor the CPR method, it applies to any type of numerical scheme discretization used in a reservoir simulation as long as the preconditioner or part of the preconditioner of the Jacobian concerns a pressure unknowns subsystem which matrix is Symmetric Positive Definite (SPD—see Y. Saad, Iterative Methods for Sparse Linear Systems (2^{nd} edition), SIAM, 2003, for mathematical definition of a SPD matrix) or close to a SPD matrix (in the sense that

$$\frac{‖ A - {A}^{t} ‖}{‖ A ‖}$$

is small compared to ∥A∥ and that eigenvectors of A^{t} A can be considered as good approximations of those of A). Due to the nature of the physical equations governing the fluid flows in porous media at any scale, the method is likely to be applied for any fluid flow simulation in a porous medium: simulation of fluid flows at the scale of a reservoir (several kilometers) or at the scale of a pore network in a rock (up to a few centimeters). As a consequence, in the rest of the document, the linear system considered for the preconditioning method described will not necessarily refer to the full Jacobian system of a reservoir simulator; it can be a system or subsystem resulting from any algebraic transformation of the Jacobian system of a reservoir simulator or system issued from any fluid flow simulator used as a pre or post stage of a reservoir simulator: the typical example being simulations at pore scale of the rocks that are used to numerically determine some rock properties needed in the reservoir simulator (those kind of simulation are usually referred to as Digital Rock Physics simulations).

The CPR method is known to be optimal when the pressure matrix A is an M-matrix, i.e. a matrix such as its inverse A⁻¹ has positive (or null) coefficients. In reservoir simulators, A is generally an M-matrix or is “close” to an M-matrix (in the sense described above).

The only applicability condition for the preconditioning method is that the considered system matrix is SPD or close to a SPD matrix (in the sense described above). There exists a number of methods to determine a proper preconditioner (or optimal preconditioner) on SPD matrix, e.g. Multi-Grid, Algebraic Multi-Grid (AMG), or multi levels Domain Decomposition methods (see V. Dolean, P. Jolivet and F. Nataf, An Introduction to Domain Decomposition Methods: algorithms, theory and parallel implementation, SIAM bookstore, 2015; and Stüben K. Algebraic Multigrid (AMG): An Introduction with Applications. Nov. 10, 1999). A preconditioning method is qualified as purely algebraic when it only requires the matrix A of the linear system for the construction of the preconditioner (non purely algebraic method are those that require additional mathematical data such as the mesh geometry, some derivative compute from the continuous equation of the initial problem, etc.). The purely algebraic nature of the preconditioner is important in reservoir simulation because the system is not necessarily directly obtained by a discretization of continuous equations: for example this is the case in the fully implicit scheme when one needs to apply a preconditioner for the pressure system produced by the CPR method. Another advantage of a purely algebraic preconditioner is that it is simpler to implement and maintain in a reservoir simulator software. The usual method used to precondition the pressure subsystem in the CPR method is the Algebraic Multi-Grid (see Stüben K. Algebraic Multigrid (AMG): An Introduction with Applications. Nov. 10, 1999), thus the CPR preconditioner is usually called the CPR-AMG method.

The pressure system or subsystem preconditioner is the performance bottleneck in a reservoir simulator running on a massively parallel supercomputer (a computer that connects a very large number of CPU units). The invention presented in this document allows building a purely algebraic preconditioning method that can replace AMG in the CPR method or be used as part of a preconditioner for a pressure linear system in a reservoir simulator.

Such technical problem has been addressed in the international application PCT/IB2017/001566. In this application, a two-level preconditioner based on a domain decomposition of the set of unknowns is considered. In the following, Ω denotes the entire domain and {Ωᵢ,i∈I}, where I is a set of indexes, is a partition of Ω in a set of subdomains Ωᵢ.

Such type of two-level preconditioner can be written in a general additive form as:

$${M}^{- 1} = {\sum }_{{Ω}_{i}} {R}_{i}^{t} {A}_{i}^{- 1} {R}_{i} + {Z ( {Z}^{t} AZ )}^{- 1} {Z}^{t}$$

where the matrix Rᵢ corresponds to a restriction operator from the global set of unknowns toward the subset of unknowns of the subdomain Ωᵢ (Rᵢ^{t} corresponds to the prolongation operator), and the matrix Aᵢ corresponds to the restriction of the global matrix A to the unknowns of subdomain i (it is noted that Aᵢ=RᵢARᵢ^{t}).

E_{Ω}_{ᵢ}Rᵢ^{t}Aᵢ⁻¹Rᵢ can be interpreted as the local solvers in the subdomains and Z(Z^{t}AZ)⁻¹Z^{t} can be interpreted as the coarse solver (or “coarse correction”). Note that other variants (such as the multiplicative form) can be written as a two-level preconditioner based on a domain decomposition (see V. Dolean, P. Jolivet and F. Nataf, An Introduction to Domain Decomposition Methods: algorithms, theory and parallel implementation SIAM bookstore, 2015 for a detailed overview of those types of preconditioners).

The main ingredient in a two-level preconditioner as formulated above is the linear operator Z.

Z is classically named a projector (or algebraic projector): it is difficult to identify a proper projector Z such that the coarse problem solution contains enough information so that the condition number of the preconditioned system can be bounded independently of the number of mesh cells used in the simulation and of the physical heterogeneity (such as rock permeability heterogeneity that influences a lot the condition number of the Jacobian system). In addition, it is important that the determination of the projector Z may be parallelized easily (i.e. that a plurality of processors may compute it without important communications between processors). Finally, in order to obtain a purely algebraic preconditioner, Z needs to be constructed only from the matrix of the linear system (we will also denote this matrix by A in the following).

In the previous system used in reservoir simulation (see AMG method), the determination of the coarsening (i.e. the projector Z) implies many communications between processors in charge of said determination. It is well known that communication between processors in parallelized tasks is a real bottleneck that should be avoided.

Nevertheless, and even if the scientists are well aware of said bottlenecks for linear systems coming from reservoir simulation, no method for the purely algebraic determination of projectors is proposed in which the communication between processors are limited to the maximum or simply avoided.

The method described in PCT/IB2017/001566 allows determining an adequate projector Z in an efficient algebraic way, which can be parallelized. In particular, the projector Z defined in this application allows projecting the matrix A on a coarser grid: Z^{t}AZ=A_{c}. In other words, the projector Z allows projecting the original linear system Ax=b on a smaller set of unknowns. However, this method is fully efficient only in the case of a two-level preconditioner.

The method of PCT/IB2017/001566 evokes a generalization to more than two levels, by recursively applying the same process to A_{c} until the size of A_{c} is correct (i.e. adequate for the use of the users computing said matrix). However, such generalization is not optimal, in particular because A_{c} is not close to an M-matrix. Actually, the larger the size of A_{c} is, the less the method is optimal. This is all the more problematic because in many cases, for instance in case of processing large blocks of data in parallel by a graphics processing unit (GPU), the size of A_{c} may indeed be very large.

There is thus a need for a method for determining an adequate projector Z in an efficient algebraic way, which can be parallelized, as part of a multi-level approach.

### SUMMARY OF THE INVENTION

The invention relates to a method implemented by computer means for determining hydrocarbon production of a reservoir, wherein the method comprises:
modeling the reservoir with a gridded model Ω comprising a plurality of cells, said gridded model having:
   a coarse partition P₂, said coarse partition having coarse subdomains {Ω_{2,j}}ⱼ,
   a fine partition P₁, said fine partition having fine subdomains {Ω_{1,i}}ᵢ, each coarse subdomain being composed of a subset of fine subdomains;
determining a first matrix A based on a Jacobian matrix function of the gridded model;
wherein each fine subdomain has a respective first order value, said first order value being function of an index of a line in a subset of consecutive lines of the first matrix corresponding to said fine subdomain,
wherein each coarse subdomain has a respective second order value, said second order value being function of an index of a line in a subset of consecutive lines of the first matrix corresponding to said coarse subdomain;
wherein the method further comprises:
splitting the first matrix into subsets of consecutive lines, each subset of consecutive lines corresponding to a respective fine subdomain Ω_{1,j}, each subset of consecutive lines being received by one dedicated processor;
for each subset of consecutive lines:
   creating a first respective square matrix Aₚₚ based on said subset;
   creating a second respective square matrix Bₚ based on said subset;
   determining extended generalized eigenvectors xᵢ and respective eigenvalues λᵢ of the first square matrix Aₚₚ and the second square matrix Bₚ;
   determining relevant eigenvectors, the relevant eigenvector being the determined eigenvectors having respective eigenvalues below a first predetermined threshold θ₁;
determining a first projector matrix Z₁ as a concatenation of the relevant eigenvectors ordered according to:
   firstly, the respective first order value of the fine subdomain Ω_{1,i} corresponding to the subset of consecutive lines for which the relevant eigenvector is determined; and
   secondly, the respective eigenvalue of the relevant eigenvector;
characterized in that the method further comprises:
for each coarse subdomain Ω_{2,p}:
   extracting a submatrix Z_{1[p]} from the first projector matrix Z₁, said submatrix Z_{1[p]} corresponding to a subset of fine subdomains {Ω_{1,i}}ᵢ composing said coarse subdomain Ω_{2,p};
   determining generalized eigenvectors wᵢ^{p} of a third square matrix and a fourth square matrix and respective eigenvalues λᵢ^{p}, said third square matrix and fourth square matrix being function of said submatrix Z_{1[p]};
   determining relevant second eigenvectors, the relevant second eigenvectors being the determined eigenvectors of the third square matrix and the fourth square matrix having respective second eigenvalues below a second predetermined threshold θ₂;
determining a projector matrix Z based on a concatenation of vectors, each vector being function of a respective relevant second eigenvector, said vectors being ordered according to:
   firstly, the second order value of the coarse subdomain Ω_{2,p} for which the respective relevant second eigenvector is determined; and
   secondly, the respective eigenvalue of the relevant second eigenvector;
determining a preconditioner operator M⁻¹ based on the projector matrix Z;
determining hydrocarbon production for the reservoir based on the preconditioner operator M⁻¹.

The Jacobian matrix (or a transformation of the Jacobian matrix as in the first stage matrix of the CPR method) may be determined by classical methods such as methods described above (i.e. using non-linear Newton iterations).

“Consecutive lines” of a matrix are lines that have a consecutive index (i.e. line number of the matrix) in said matrix: most of the time the index of a matrix is comprised between 1 (i.e. the first line of the matrix) and the number of lines (i.e. the last line of the matrix).

The order of the subsets may be function of the index of the lines that are in said subset: therefore, the order value of a subset that comprises lines 1-10 may be 1, the order value of a subset that comprises lines 11-15 may be 2, the order value of a subset that comprises lines 16-25 may be 3, etc.

This definition is equivalent to the following: the order of a given subset may be equal or function of the number of subsets having at least one line with a respective index lower than any index of lines that are in said given subset.

By creating a square matrix for each subset (the dimension of the square matrix is equal to the number of lines in the given subset), it is possible to allocate a specific task to a plurality of processors (i.e. determining the eigenvalues and eigenvectors). This task may be performed independently to any other tasks given to other processors. Therefore, the processors do not need to communicate and avoid any bottleneck as described above.

When each processor ends its respective tasks, the projector may be determined by simply extending the eigenvector to the dimension of the global system matrix by adding zeros at indexes of lines not in the subset and then concatenating the extended eigenvectors (horizontal concatenation, i.e. if k vectors should be concatenated, the final matrix has a width of k and a height of the height of the vectors).

In one or several embodiments, the determining of the first matrix A may comprise:
permuting a Jacobian matrix function of the gridded model according to an ordering of unknowns involved in a computation of flow rates in the gridded model, each unknown having a respective index in said permutation, the permutation being performed so that all unknowns related to a same partition among the coarse partition and fine partition have contiguous indexes in the new ordering and so that inside each contiguous set of indexes, the unknowns of cells that are connected have an index greater than the indexes of unknowns of cells that have no connection;
determining a first matrix A based on the permutation of the Jacobian matrix.

The method requires that the lines of the Jacobian matrix J_{X1} corresponding to the division into subdomains be contiguous. When it is not the case, it is possible to use a permutation to do so. Furthermore, ordering unknowns corresponding to a same subdomain so that the unknowns of cells located on an edge of the subdomain connected to another subdomain correspond to lines of higher indexes compared to other unknowns (i.e. unknowns that are not on an edge) may optimize the solving of the eigenvalue problem.

In one or several embodiments, each line of the first matrix A may belong to only one subset among the subsets of consecutive lines.

In other words, each line of the matrix A is in a subset, and no line is more than once in a subset.

In one or several embodiments, for a partition among the fine partition and the coarse partition, the order value of the first subdomain may be greater than the order value of the second subdomain if:
a first subdomain of the partition corresponds to a first subset of consecutive lines of the first matrix A,
a second subdomain of the partition corresponds to a second subset of consecutive lines of the first matrix A, and
the first subset has a line subsequent to a line of the second subset.

Therefore, the respective order value of the subsets increases while the index of the lines comprised in said subset increases.

In one or several embodiments, the method may further comprise:
for each determined relevant second eigenvector wᵢ^{p}, determining a respective extended relevant second eigenvector xᵢp;
   and the determining of the projector matrix Z may comprise:
determining a second projector matrix Z₂ as a concatenation of the extended relevant second eigenvectors xᵢ^{p} ordered according to:
   firstly, the second order value of the coarse subdomain Ω_{2,p} for which the respective relevant second eigenvector is determined; and
   secondly, the respective eigenvalue of the relevant second eigenvector;
determining the projector matrix Z based on the first projector matrix Z₁ and the second projector matrix Z₂.

In addition, the projector matrix Z may be a product of the first projector matrix Z₁ and the second projector matrix Z₂.

In one or several embodiments, the method may comprise:
for each determined relevant second eigenvector wᵢ^{p}, determining a respective vector Vᵢ^{p} as a function of a product of the relevant second eigenvector wᵢ^{p} and the submatrix Z_{1[p]} corresponding to the coarse subdomain Ω_{2,p} for which the respective relevant second eigenvector is determined;
wherein the projector matrix Z is a concatenation of the determined vector Vᵢ^{p} ordered according to:
firstly, the second order value of the coarse subdomain Ω_{2,p} for which the respective relevant second eigenvector is determined; and
   secondly, the respective eigenvalue of the relevant second eigenvector.

In addition, each vector Vᵢ^{p} may be an extended vector derived from a product of the submatrix Z_{1[p]} and the relevant second eigenvector wᵢ^{p}.

In one or several embodiments, the first predetermined threshold θ₁ may be greater than or equal to the second predetermined threshold θ₂.

In one or several embodiments, the preconditioner operator M⁻¹ may be function of Z(Z^{t}AZ)⁻¹Z^{t}, Z being the determined projector matrix and A being the first matrix.

Another object of the invention relates to a non-transitory computer readable storage medium, having stored thereon a computer program comprising program instructions, the computer program being loadable into a data-processing unit and adapted to cause the data-processing unit to carry out the steps of any of the above methods when the computer program is run by the data-processing device.

Yet another object of the invention relates to a device for determining hydrocarbon production for a reservoir, wherein the device comprises an interface to receive information of the reservoir,
wherein the device comprises a first processor adapted for:
   modeling the reservoir with a gridded model Ω comprising a plurality of cells, said gridded model having:
      a coarse partition P₂, said coarse partition having coarse subdomains {Ω_{2,j}}ⱼ,
      a fine partition Pₜ said fine partition having fine subdomains {Ω_{1,i}}ᵢ, each coarse subdomain being composed of a subset of fine subdomains;
   determining a first matrix A based on a Jacobian matrix function of the gridded model;
wherein each fine subdomain has a respective first order value, said first order value being function of an index of a line in a subset of consecutive lines of the first matrix A corresponding to said fine subdomain,
wherein each coarse subdomain has a respective second order value, said second order value being function of an index of a line in a subset of consecutive lines of the first matrix A corresponding to said coarse subdomain;
wherein the method further comprises:
   splitting the first matrix A into subsets of consecutive lines, each subset of consecutive lines corresponding to a respective fine subdomain Ω_{1,j}, each subset of consecutive lines being received by one dedicated processor;
wherein the device further comprises a plurality of processors, each subset of consecutive lines being received by one dedicated processor in said plurality of processors;
   wherein, for each subset of consecutive lines, a processor in the plurality of processor is configured for:
      creating a first respective square matrix Aₚₚ based on said subset;
      creating a second respective square matrix Bₚ based on said subset;
      determining extended generalized eigenvectors xᵢ and respective eigenvalues λᵢ of the first square matrix Aₚₚ and the second square matrix Bₚ;
      determining relevant eigenvectors, the relevant eigenvector being the determined eigenvectors having respective eigenvalues below a first predetermined threshold θ₁;
wherein the first processor is further configured for:
   determining a first projector matrix Z₁ as a concatenation of the relevant eigenvectors ordered according to:
      firstly, the respective first order value of the fine subdomain Ω_{1,i} corresponding to the subset of consecutive lines for which the relevant eigenvector is determined; and
      secondly, the respective eigenvalue of the relevant eigenvector;
characterized in that the first processor is further configured for:
   for each coarse subdomain Ω_{2,p}:
      extracting a submatrix Z_{1[p]} from the first projector matrix Z₁, said submatrix Z_{1[p]} corresponding to a subset of fine subdomains {Ω_{1,i}}ᵢ composing said coarse subdomain Ω_{2,p};
      determining generalized eigenvectors wᵢ^{p} of a third square matrix and a fourth square matrix and respective eigenvalues λᵢ^{p}, said third square matrix and fourth square matrix being function of said submatrix Z_{1[p]};
      determining relevant second eigenvectors, the relevant second eigenvectors being the determined eigenvectors of the third square matrix and the fourth square matrix having respective second eigenvalues below a second predetermined threshold θ₂;
   determining a projector matrix Z based on a concatenation of vectors, each vector being function of a respective relevant second eigenvector, said vectors being ordered according to:
      firstly, the second order value of the coarse subdomain Ω_{2,p} for which the respective relevant second eigenvector is determined; and
      secondly, the respective eigenvalue of the relevant second eigenvector;
   determining a preconditioner operator M⁻¹ based on the projector matrix Z;
determining hydrocarbon production for the reservoir based on the preconditioner operator M⁻¹.

Other features and advantages of the method and apparatus disclosed herein will become apparent from the following description of non-limiting embodiments, with reference to the appended drawings.

### BRIEF DESCRIPTION OF THE DRAWINGS

The present invention is illustrated by way of example, and not by way of limitation, in the figures of the accompanying drawings, in which like reference numerals refer to similar elements and in which:

FIG. 1 is a diagram describing a process of solving a flow problem;

FIGS. 2a to 2g represent a method of the prior art for determining a projector Z;

FIG. 3 represents two nested partitions of the domain in a possible embodiment of the present invention;

FIG. 4 is a representation of the part of the projector Z₁ corresponding to the p-th subdomain of the coarse partition;

FIG. 5 represents the reduction of the dimension of the generalized eigenvalue problem in a possible embodiment of the present invention;

FIG. 6 is a flow chart describing a possible embodiment of the present invention;

FIG. 7 is a possible embodiment for a device that enables the present invention;

FIG. 8 is a representation of submatrices corresponding to the p-th subdomain of the coarse partition.

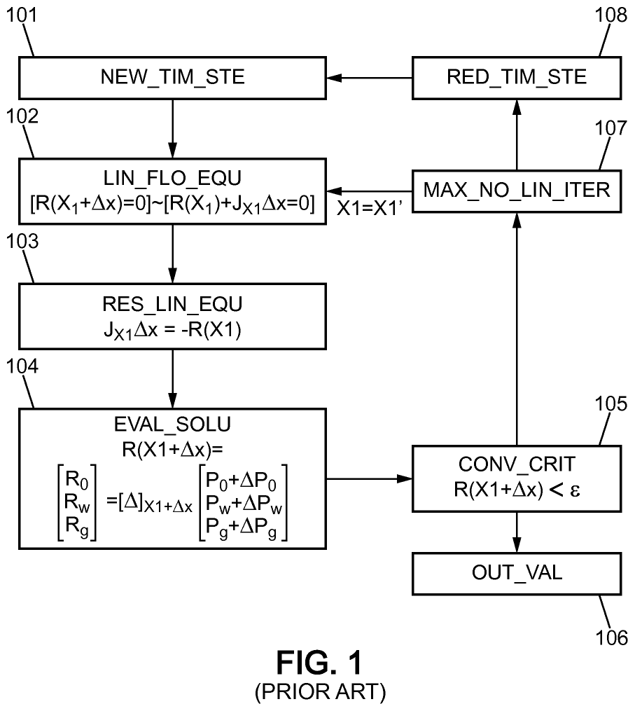

### DESCRIPTION OF PREFERRED EMBODIMENTS

For the purpose of simplification, the Jacobian matrix J_{X1} or a transformation of the Jacobian matrix (for instance, by permuting lines or columns of J_{X1} as detailed below) is noted in the following description A.

It is assumed that lines or columns of the Jacobian matrix J_{X1} may be beforehand permuted according to an ordering of unknowns. Indeed, the Jacobian matrix J_{X1} obtained by using an arbitrary ordering of unknowns involved in the computation of flow rates in the gridded model is generally not adapted to the method for determining hydrocarbon production of the reservoir, which requires that the lines (or the column, depending on the equations considered) of the matrix corresponding to the division into subdomains be contiguous. Therefore, a permutation of the lines/columns of J_{X1} may be used to ensure that the unknowns of each subdomain of a partition have contiguous indexes, while maintaining (if possible and if the original is symmetric) the symmetry of the matrix. Furthermore, it may be interesting, in terms of optimization of the method, to impose an ordering of unknowns corresponding to a same subdomain so that the unknowns of cells located on an edge of the subdomain connected to another subdomain correspond to lines of higher indexes compared to other unknowns (i.e. unknowns that are not on an edge). Such an ordering optimizes the calculations involved in solving the eigenvalue problem relating to this subdomain.

The purpose of determining the projector Z is to determine a proper preconditioner matrix M⁻¹ and thus to ease the determination of hydrocarbon production in reservoirs for oil/gas industry.

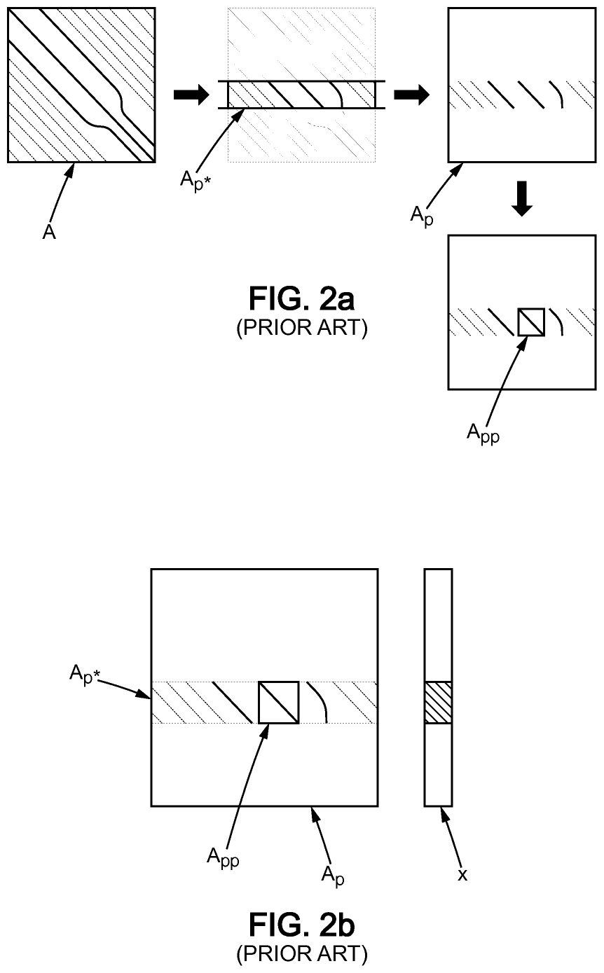

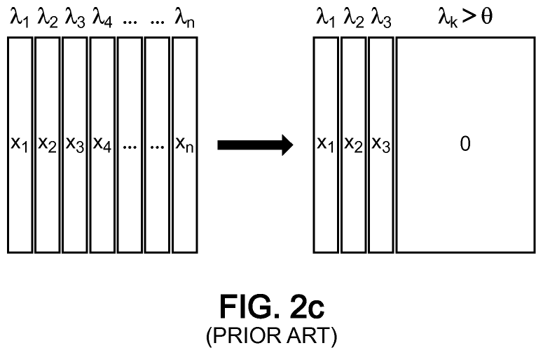

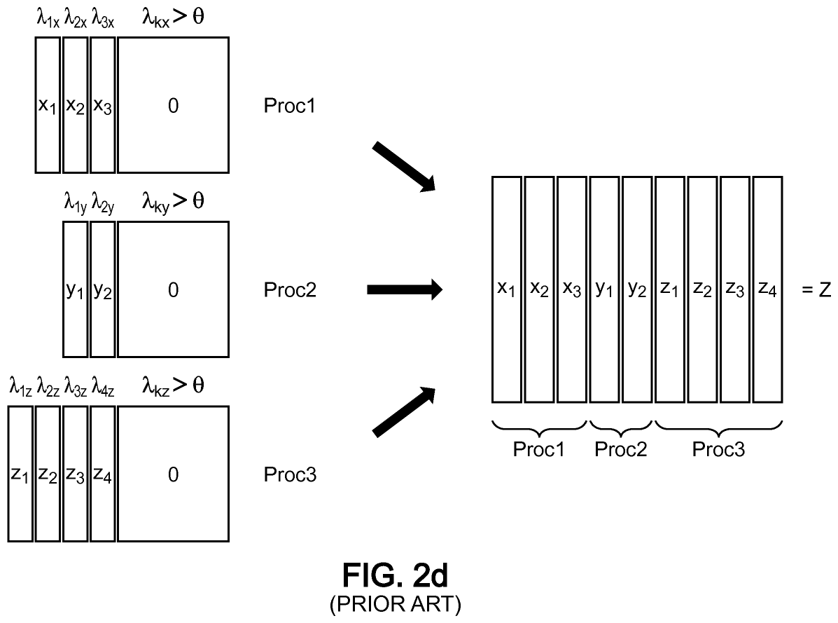

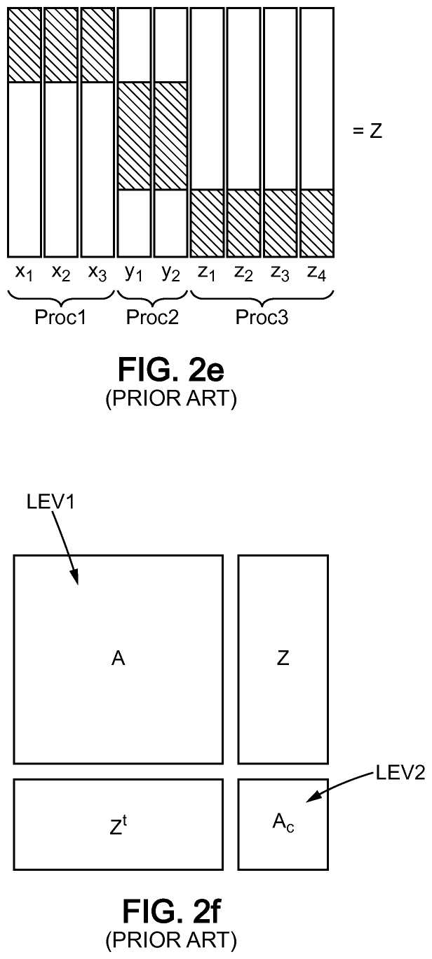

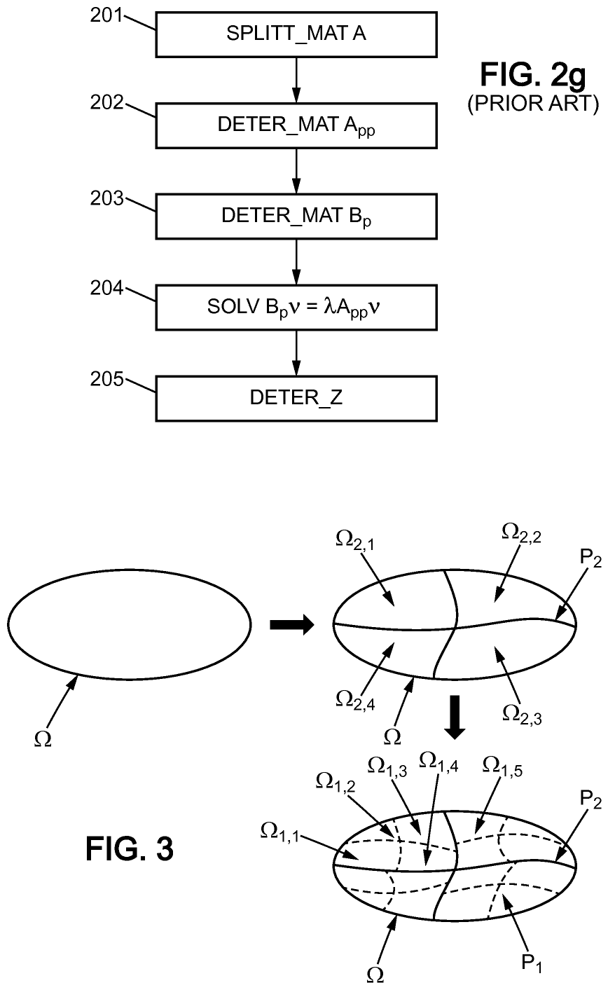

FIGS. 2a to 2g represent a method described in PCT/IB2017/001566 for determining a projector Z, in the case where a single partition {Ωᵢ, i∈I} of the domain Ω is considered.

FIG. 2a represents an example of a square matrix A of dimensions n×n. The matrix A is usually a sparse matrix, in which many values (blank zones in the representation of matrix A) are null. This property is mainly due to the fact that the interactions between cells are limited to the neighboring cells.

In order to parallelize the task, a slice of the matrix A is determined for each processor p: the first processor receives the first k₁ lines (e.g. the order number of said subset comprising the first k₁ lines may be 1), the second processor receives the next k₂ subsequent lines (e.g. the order number of said subset comprising the next k₂ subsequent lines may be 2), the third processor receives the next k₃ subsequent lines (e.g. the order number of said subset comprising the next k₃ subsequent lines may be 3), etc. The number k₁, k₂, k₃, etc. may be identical but it is not mandatory: it is possible to have a different number of lines if the load/capacity/performance/number of available flops/etc. are different for each processor.

This slicing is a splitting of the Jacobian matrix into subsets of consecutive lines.

The subset of line corresponding to the restriction of the matrix Aₚ to the received lines is denoted A_{p*}.

Each processor p then determines a square matrix Aₚ with the received lines (at the same position that in the original matrix). The new matrix Aₚ may then be regarded as (the following assertions are equivalent):
the matrix A where the non-received lines are set to zero;
a null matrix where the received lines are copied at a position identical to their original position in the matrix A; or
a matrix where:
   line having index equal to the index of a second line in the received lines is identical to said second line; and
   line having no index equal to the index of a second line in the received lines is a line with 0-values.

Then, a square matrix Aₚₚ is obtained by considering the restriction of A_{p*} to the columns which indexes are in the p^{th} subset of indexes, as represented in FIG. 2a.

A square matrix Bₚ is then obtained by adding all the entries A_{p*}(i,j) that are outside the square matrix Aₚₚ in the diagonal coefficient Aₚₚ (i,i) of Aₚₚ (the indexing X(i,j) refers to a coefficient in the i^{th} line and j^{th} column the considered matrix X).

It is then possible to compute the eigenvalues λ and eigenvectors v of the generalized eigenvalue problem: Bₚv=λAₚₚv such that λ<θ with θ∈[0, 1] (it can be proven that all eigenvalues λ are in [0, 1]).

When A is a symmetric positive definite (SPD) matrix, then Aₚₚ is also an SPD matrix. Thus, we can write the Cholesky_decomposition of Aₚₚ=LL^{t}, where L is a lower triangular matrix (see https://en.wikipedia.org/wiki/Cholesky_decomposition) to transform the generalized eigenvalue problem into:

Bₚv=λLL^{t}v

Thus it is noticeable that the eigenvectors v can be equivalently computed as v=(L^{t})⁻¹w, with w being the eigenvector solution to the eigenvalue problem L⁻¹Bₚ(L^{t})⁻¹w=λw.

When A is not strictly an SPD matrix, the adaptation of the projector Z construction relies upon this reformulated eigenvalue problem. When A is not a symmetric positive definite matrix (which is the case if we want to apply our method as a more parallel replacement for AMG in the CPR-AMG method where the matrix is not perfectly symmetric) we adapt the method as follows:
instead of computing the Cholesky decomposition, we compute the L.D.U decomposition of the square matrix Aₚₚ (as defined in https://en.wikipedia.org/wiki/LU_decomposition). In practice, for reservoir simulation, we assume that this decomposition is always possible without considering a permutation of Aₚₚ as in the general formula. But if such a case was encountered, a simple line permutation of the A_{p*} matrix would also allow writing the L.D.U decomposition without having to use a permutation matrix. In this decomposition L is a lower triangular matrix with unitary coefficients on the diagonal, D is a diagonal matrix and U is an upper triangular matrix with unitary coefficients on the diagonal;
we consider the matrix S that is the diagonal matrix obtained from D such that the diagonal coefficient S(i,i) of S are computed as S(i,i)=sqrt(abs(D(i,i))) where S(i,i) and D(i,i) are respectively the coefficient in line i and column i of S and D, abs(x) is the absolute value of x and sqrt(x) is the square root of x;
we compute the square matrix Mₚ=S⁻¹L⁻¹BₚU⁻¹S⁻¹;
we build the square symmetric matrix Kₚ=Mₚ (Mₚ)^{t};
given the chosen threshold θ>0, we select all the eigenvectors w solution of Kₚw=λw such that λ<θ²;
finally we obtain the set of eigenvectors v needed by computing v=U⁻¹S⁻¹w for any w computed at the previous step.

One can notice that if we apply these more general computations in the case where A is SPD, we end up with the same eigenvectors as with the computations for the previous method dedicated to the purely SPD case (but in a less optimized manner since we do at least some extra computations to obtain Kₚ).

As mentioned above, it may be interesting to impose a prior ordering of lines or columns of the matrix A so that, for unknowns corresponding to a same subdomain, the unknowns of cells located on an edge of the subdomain connected to another subdomain correspond to lines of higher indexes compared to other unknowns (i.e. unknowns that are not on an edge). This ordering allows optimizing the solving of the generalized eigenvalue problem Bₚv=λAₚₚv corresponding to each subdomain.

For instance, when matrix Aₚₚ is purely SPD, a Choleski decomposition of Aₚₚ may be performed: Aₚₚ=LL^{t}. Thus, the above generalized eigenvalue problem may be reduced to a simpler eigenvalue problem by posing v=L^{-t}w (where L^{-t}=(L^{t})⁻¹):

(L⁻¹BₚL^{-t})w=λw

Bₚ is equal to matrix Aₚₚ everywhere except for lines that have connections with unknowns in other subdomains. When all the unknowns that are on the edges of the subdomain p are ordered last by the prior ordering, it follows that the matrix Bₚ differs from Aₚₚ only on the diagonal coefficients which are all grouped at the end of the matrix Bₚ. Bₚ may thus be written:

$${B}_{p} = {A}_{pp} + ( \begin{matrix}0 & 0 \\ 0 & D\end{matrix} )$$

where D is a diagonal matrix having a dimension equal to the number of unknowns on the edges of the subdomain p. Since L⁻¹AₚL^{-t}=I, then:

$${L}^{- 1} {B}_{p} {L}^{- 1} = I + {L}^{- 1} ( \begin{matrix}0 & 0 \\ 0 & D\end{matrix} )$$

$${L}^{- t} = I + ( \begin{matrix}0 & 0 \\ 0 & K\end{matrix} )$$

where

$$( \begin{matrix}0 & 0 \\ 0 & K\end{matrix} ) = {L}^{- 1} ( \begin{matrix}0 & 0 \\ 0 & D\end{matrix} ) {L}^{- t}$$

is a matrix having a dimension much smaller than Bₚ, because K has a dimension equal to the number of unknowns on the edges of the subdomain p.

Hence, the problem (L⁻¹Bₚ L^{-t})w=λw may be simplified into a problem of smaller dimension: Kw_{boundary}=λw_{boundary}, where w_{boundary} is the restriction of w to the unknowns of edges. By filling w_{boundary} filled with zero values, the eigenvectors w of the complete problem on all the unknowns of the subdomains. Then, the following change of variable may be applied: v=L^{-t}w.

Once the eigenvectors have been computed each vector v is prolonged into a vector x of the same dimension than the A matrix by completing with zero values for the indexes that do not correspond to a received line.

With reference to FIG. 2b, this means that, in the vector x, the values that are not in the hatched zone (i.e. zone corresponding to the received lines) may be set to zero.

When the n eigenvalues {λₖ}_{k∈n} and the n eigenvectors {xₖ}_{k∈n} are determined, it is possible to order the eigenvectors {xₖ}_{k∈n} according to the order of the corresponding λₖ (ascending order). In the example of FIG. 2c, λ₁≤λ₂≤λ₃≤ . . . ≤λₙ. As represented in FIG. 2c, the eigenvectors having respective eigenvalues greater than a predetermined threshold θ may be set to zero.

Then, all the non-identified eigenvectors, for each processor having received lines from the matrix A, may be concatenated, in the order of the sequence of lines (i.e. order number of the subset of lines) that has been received by the processor:
if the processor Proc1 has received the first lines, the identified eigenvectors for said processor is retrieved and forms the first columns of a new matrix Z (in the example of FIG. 2d, three eigenvectors have been identified for Proc1, said processor Proc1 having received the first lines of the matrix A);
if the processor Proc2 has received a number of immediate subsequent lines (i.e. after the lines of Proc1), the identified eigenvectors for said processor is retrieved and forms the immediate subsequent columns of the new matrix Z (in the example of FIG. 2d, two eigenvectors have been identified for Proc2, said processor Proc2 having received the immediate subsequent lines of the matrix A, after the lines of Proc1);
if the processor Proc3 has received a number of immediate subsequent lines (i.e. after the lines of Proc2), the identified eigenvectors for said processor is retrieved and forms the immediate subsequent columns of the new matrix Z (in the example of FIG. 2d, four eigenvectors have been identified for Proc3, said processor Proc3 having received the immediate subsequent lines of the matrix A, after the lines of Proc2).

This is equivalent to determining eigenvectors having respective eigenvalues below a predetermined threshold (θ) as relevant eigenvectors and concatenating said relevant eigenvectors according:
firstly, the respective order number of the subset for which the relevant eigenvector is determined;
secondly, the respective eigenvalue of the relevant eigenvector.

It is noted that there are two criteria for the ordering: it means that, first, the groups of eigenvectors (i.e. one group per processor) are ordered according to respective order number of the subset for which the relevant eigenvectors are determined, and then each group of eigenvectors are ordered according to the respective eigenvalue.

As represented in FIG. 2b, the eigenvectors have null values in zones that do not correspond to the received lines. Therefore, and as shown in FIG. 2e, the Z matrix is formed of diagonal blocks, outside said block the value of Z is zero (see white zones of the vectors xᵢ,yᵢ,zᵢ in FIG. 2e). The Z matrix has a height of n, the width of matrix Z is m, m being lesser or equal to n (depending of the value of the threshold θ: the lesser θ is, the lesser m is). Said matrix Z allows projecting the matrix A (LEV1) on a coarser grid, Z^{t} AZ=A_{c} (see LEV2, FIG. 2f).

Once matrix Z have been determined, the preconditioner M may be calculated.

FIG. 2g is a flow chart of a method described in PCT/IB2017/001566 for determining a projector Z.

As described above, the matrix A may first be splitted 201 into a plurality of subsets of consecutive lines. Then, for each subset of consecutive lines, the respective square matrix Aₚₚ may be determined 202. The respective square matrix Bₚ may then be determined 203 by adding all the entries A_{p*}(i,j) that are outside the square matrix Aₚₚ in the diagonal coefficient Aₚₚ (i,i) of Aₚₚ.

Then, the eigenvalues λ and eigenvectors v of the generalized eigenvalue problem: Bₚv=λAₚₚv may be found 204. It is possible to keep only the “relevant” eigenvectors, i.e. the eigenvectors associated with eigenvalues λ below a predefined threshold θ (λ<θ). The relevant eigenvectors v may then be prolonged into vectors x of the same dimension than the A matrix by completing with zero values for the indexes that do not correspond to a received line.

Finally, the projector Z may be determined 205 based on the prolonged relevant eigenvectors x determined for all subsets of consecutive lines. For instance, the projector Z may be a concatenation of the relevant eigenvectors ordered according to multiple criteria:
firstly, the respective order number of the subset for which the relevant eigenvector is determined; and
secondly, the respective eigenvalue of the relevant eigenvector.

The preconditioner M may then be calculated based on the projector Z, for instance according to the following formula:

$${M}^{- 1} = {\sum }_{{Ω}_{i}} {R}_{i}^{t} {A}_{i}^{- 1} {R}_{i} + {Z ( {Z}^{t} AZ )}^{- 1} {Z}^{t}$$

with {Ωᵢ}ᵢ a set of local domain/space. Of course, other formula linking M and Z may be used.

As mentioned above, this algorithm is fully efficient in the case of a single partition of the domain Ω (i.e. a two-level representation of the space), but it does not provide good results in the case of multilevel (i.e. a number of levels strictly higher than 2) representation of space. The present invention proposes an alternative efficient multilevel algorithm.

In the following, it is considered two nested partitions of the reservoir gridblocks. Of course, the proposed method may be used for more than two nested partitions.

FIG. 3 represents two nested partitions of the domain (i.e. the set of unknowns) Ω. The domain Ω is divided into a first partition P₂={Ω_{2,i}}_{∈I}_{₂}, called “coarse” partition, represented in full lines in FIG. 3. The domain Ω may also be divided into a second partition P₁={Ω_{1,i}}_{i∈I}_{₁}, called “fine” partition, represented in dashed lines in FIG. 3. The fine partition P₁ is defined such that each subdomain Ω_{2,i} of the coarse partition may be decomposed into a union of at least one subdomain Ω_{1,j} of the fine partition (i.e. for each subdomain Ω_{2,i} of the coarse partition, there is a subset of at least one subdomain Ω_{1,j} which is a partition of Ω_{2,i}). Such partitions are called “nested” partitions.

Each partition of the domain comprises a plurality of subdomains, and each subdomain of a partition comprises (or “covers”) a plurality of cells of the gridded model.

For each partition, it is assumed that each subdomain has a respective order value.

As mentioned above, the matrix A may be splitted into a plurality of subsets of consecutive lines, each subset corresponding to a subdomain of a given partition.

For instance, the first k₁ lines of A may correspond to the first subdomain Ω_{1,1} of the fine partition, the k₂ lines of A immediately subsequent to the k₁-th line may correspond to the second subdomain Ω_{1,2} of the fine partition, the k₃ lines of A immediately subsequent to the k₂-th line may correspond to the third subdomain Ω_{1,3} of the fine partition, etc.

Similarly, the first r₁ lines of A may correspond to the first subdomain Ω_{2,1} of the coarse partition, the r₂ lines of A immediately subsequent to the r₁-th line may correspond to the second subdomain Ω_{2,2} of the coarse partition, the r₃ lines of A immediately subsequent to the r₂-th line may correspond to the third subdomain Ω_{2,3} of the coarse partition, etc.

The order value of a subdomain may be function of the index of the lines that are in a subset of lines corresponding to the subdomain. For instance, the order value of the first subdomain Ω_{1,1} of the fine partition may be equal to 1, the order value of the second subdomain Ω_{1,2} of the fine partition may be equal to 2, etc. Similarly, the order value of the first subdomain Ω_{2,1} of the coarse partition may be equal to 1, the order value of the second subdomain Ω_{2,2} of the coarse partition may be equal to 2, etc.

The preconditioner M⁻¹ may be decomposed on these two nested partitions. For instance, the following additive formula may be considered:

$${M}^{- 1} = {\sum }_{{Ω}_{1 , i}} {R}_{1 , i}^{t} {A}_{1 , i}^{- 1} {R}_{, 1 , i} + ( {\sum }_{{Ω}_{2 , p}} {R}_{2 , p}^{t} {Z}_{1 [ p ]} {A}_{2 , [ p ]}^{- 1} {Z}_{1 [ p ]}^{t} {R}_{2 , p} ) + {Z}_{1} {{Z}_{2} ( {Z}_{2}^{t} {Z}_{1}^{t} {AZ}_{1} {Z}_{2} )}^{- 1} {Z}_{2}^{t} {Z}_{1}^{t}$$

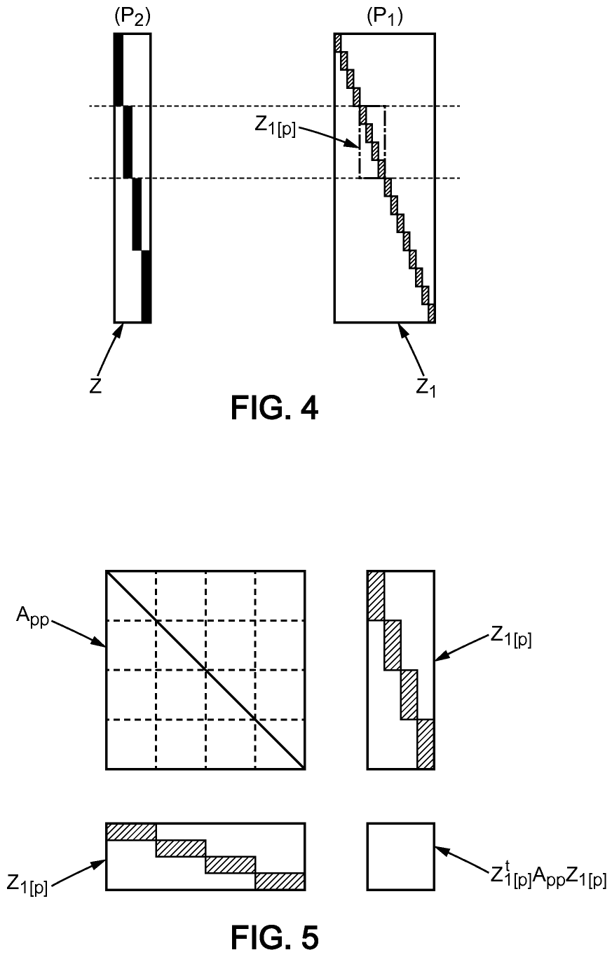

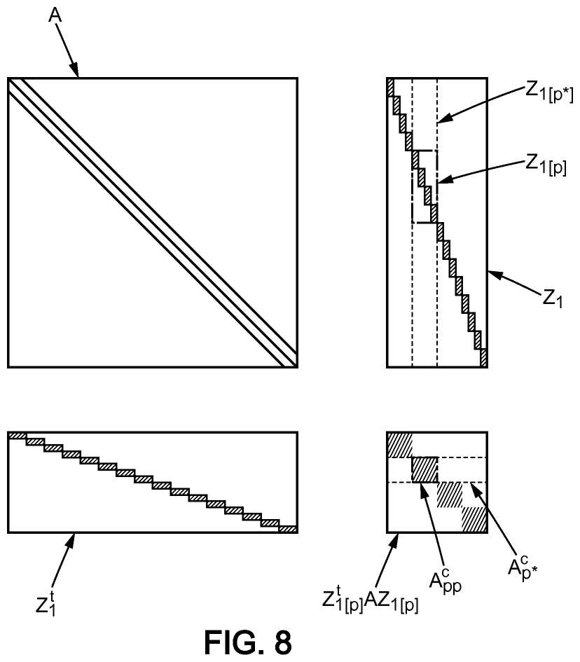

Let's introduce a few notations that will be used in the following and also to explicit this formula:
The matrices R_{1,i} correspond to a restriction operator from the global set of unknowns toward the subset of unknowns of the i-th subdomain of the partition P₁;
The matrices A_{1,i} correspond to the restriction of the global matrix A to the unknowns of the i-th subdomain of the partition P₁ (A_{1,i}=R_{1,i}AR_{1,i}^{t});
The matrices R_{2,p} correspond to a restriction operator from the global set of unknowns toward the subset of unknowns of the p-th subdomain of the partition P₂;
Z_{1[p]} denotes the restriction of Z₁ corresponding to the subdomains Ω_{1,i} of the partition P₁ that compose the subdomain Ω_{2,p}, as represented in FIG. 4 (the black parts of Z are the blocks obtained by applying the two-level method to the coarse partition P₂, and the striped parts of Z₁ are the blocks obtained by applying the two-level method to the fine partition P₁);
The matrix A_{2,[p]} is the submatrix corresponding to the restriction of the global coarse matrix to the coarse unknowns representing the subdomain p in the coarse partition P₂. We have A_{2,[p]}=Z_{1[p]}^{t}A_{2,p},Z_{1[p]}. Note that in FIG. 8, Aₚₚ^{c} corresponds to the matrix A_{2,[p]} with this notation and in FIG. 5 A_{2,p}, is represented by Aₚₚ.

Of course, the present invention is not limited to the above formula. Other expressions are possible, such as a multiplicative form of the three-level preconditioner based on a decomposition of the domain on two nested partitions. Another possible formulation consists in considering a recursive formulation of the method in PCT/IB2017/001566 where Z₁ is used to build the preconditioner M₁⁻¹=Σ_{Ω}_{_{1,i}}R_{1,i}^{t}A_{1,i}⁻¹R_{1,i}+Z₁(Z₁^{t}AZ₁)⁻¹Z₁^{t} and Z₂ is used in the same manner to build a preconditioner for the matrix A_{c}=Z₁^{t}AZ₁ in order to solve the inverse (Z₁^{t}AZ₁)⁻¹ problem in the formula of M₁⁻¹ by a preconditioned iterative method (we consider the partition on the set of coarse unknowns induced by the partition P₂).

Z₁ corresponds to the projector associated to the fine partition P₁ and may be computed according to the method of PCT/IB2017/001566 recalled above. A first threshold θ₁ may be chosen for determining the “relevant” eigenvectors.

As represented in FIG. 4, Z₁ is a block diagonal matrix where the k^{th} diagonal block is of size (nₖ, mₖ) where nₖ is the number of unknowns in the subdomain k and mₖ is the number of relevant eigenvectors.

The present invention aims to determine a projector Z₂ such that the product Z₁Z₂ is equivalent, in terms of convergence, to the projector Z that would be obtained by applying the two-level method (i.e. the method of PCT/IB2017/001566) to the coarse partition P₂.

In other words, Z_{1[p]} is composed of the eigenvectors v corresponding to the subdomains Ω_{1,i} of the partition P₁ that compose the subdomain Ω_{2,p}, wherein each relevant eigenvectors v has been prolonged into a vector x′ of the same height than the number of lines of the restriction of Z₁ to the subdomain Ω_{2,p} by completing with zero values for the indexes that do not correspond to a received line.

For determining Z₂, the invention proposes to solve the generalized eigenvalue problem

Bₚv=λA_{PP}v (1)

associated to the p-th subdomain Ω_{2,p} of the coarse partition P₂. To solve problem (1), it is assumed that a good solution can be found within the subspace generated by the columns of Z_{1[p]}. The following change of variable may thus be performed: v=Z_{1[p]}w.

According to this change of variable, a solution of problem (1) may be found by resolving the following generalized eigenvalue problem:

Z_{1[p]}^{t}BₚZ_{1[p]}w=λZ_{1[p]}^{t}AₚₚZ_{1[p]}w (2)

The interest of the above change of problem is that problem (2) is computationally much cheaper to solve than problem (1), because the dimensions of the matrices Z_{1[P]}^{t}BₚZ_{1[p]} and Z_{1[P]}^{t}AₚₚZ_{1[p]} are much smaller than the dimensions of the matrices Bₚ and Aₚₚ, as represented in FIG. 5.

The eigenvalues λ and eigenvectors w of the general eigenvalue problem (2): Z_{1[p]}^{t}BₚZ_{1[p]}w=λZ_{1[p]}^{t}AₚₚZ_{1[p]}w may be computed for all p∈I₂ (i.e. for all the subdomains Ω_{2,p} of the coarse partition P₂). It has to be noticed that Z_{1[p]}^{t}AₚₚZ_{1[p]} has the same SPD (or approximate SPD) properties than Aₚₚ.

In addition, a second threshold θ₂ may be chosen for determining the “relevant” eigenvectors w. For instance, it may be decided to keep only the eigenvectors w associated with eigenvalues λ below the predefined second threshold θ₂ (i.e. such that λ<θ₂), with θ₂ ∈[0, 1]. In one embodiment, θ₁ and θ₂ may be fixed such that θ₁≥θ₂. Furthermore, θ₁ and θ₂ may be chosen as being close (i.e. |θ₁−θ₂|≤ε, where s is a predefined real value small enough, for instance ε=0.1 or ε=0.05).

Each relevant eigenvector w may be prolonged into a vector x of the same height than the matrix A_{c} by completing with zero values for the indexes that do not correspond to a received line, as in the method of PCT/IB2017/001566 (see vector x in FIG. 2b).

For each of subdomain Ω_{2,p} (with p∈I₂) of the coarse partition P₂, the general eigenvalues {λₖ^{p}}ₖ and the corresponding prolonged vectors {xₖ^{p}}ₖ may thus be determined. It is then possible to order the vectors {xₖ^{p}}ₖ according to the order of the corresponding λₖ^{p} (for instance, an ascending order: λ₁^{p}≤λ₂^{p}≤λ₃^{p}≤ . . . ). The eigenvectors having respective eigenvalues greater than the predetermined threshold θ₂ may be set to zero.

The part Z₂^{p} of the projector Z₂ associated to the subdomain Ω_{2,13} may then be determined based on the ordered prolonged vectors xₖ^{p}. For instance, Z₂^{p} may be obtained by concatenating the relevant eigenvectors xₖ^{p} according to the respective eigenvalue of the relevant eigenvector.

The projector Z₂ may then be obtained by concatenating the Z₂^{p}, for all p∈I₂ (i.e. for all the subdomains Ω_{2,p} of the coarse partition P₂), according to the respective order value of the subdomain Ω_{2,p}.

This is equivalent to determining vectors xₖ^{p} corresponding to eigenvectors wₖ^{p} having respective eigenvalues below the predetermined threshold (θ₂) for all p∈I₂ and concatenating said vectors xₖ^{p} according to:
firstly, the respective order value of the subdomain Ω_{2,p} for which the vector xₖ^{p} is determined; and
secondly, the respective eigenvalue of the relevant eigenvector.

Once Z₂ is determined, the projector Z may be computed as follows: Z=Z₁Z₂.

Equivalently, for each relevant eigenvector w, a vector v may be computed according to v=Z_{1[p]}w. Then, each selected vector v may be prolonged into a vector V of the same height than the matrix A, by completing with zero values for the indexes that do not correspond to a received line. The projector Z may then be obtained by concatenating the vectors Vₖ^{p} determined for all p∈I₂ (i.e. for all the subdomains Ω_{2,p} of the coarse partition P₂), according to:
firstly, the respective order value of the subdomain Ω_{2,p} for which the vector Vₖ^{p} is determined; and
secondly, the respective eigenvalue of the relevant eigenvector.

Of course, the present invention may be applied for any number of levels: the projector Zₗ₊₁ of a higher partition level (Pₗ₊₁) applied to the coarse system can be determined from the projector Zₗ of a lower partition level (Pₗ, Pₗ being a subpartition of Pₗ₊₁) according to the above method, with two respective thresholds θₗ₊₁, θ₁ (for instance, on can choose θₗ≤θₗ₊₁).

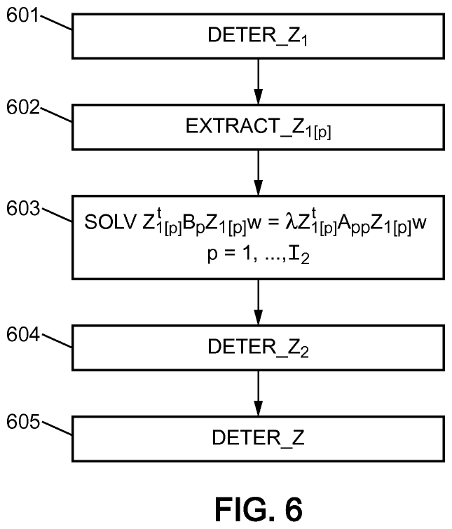

FIG. 6 is a flow chart of a method for determining a projector Z in one embodiment of the present invention.

As described above, the projector Z₁ associated to the fine partition P₁ may first be determined 601 based on the method of PCT/IB2017/001566 recalled above, with a first threshold θ₁.

For each subdomain Ω_{2,p} of P₂, a corresponding submatrice Z_{1[p]} may be extracted 602 from the determined projector Z₁. Each Z_{1[p]} is the part of Z₁ corresponding to the subdomains Ω_{1,i} of P₁ that constitute the subdomain Ω_{2,p} of P₂ (a submatrice Z_{1[p]} thus defined is represented in FIG. 4).

Then, for each p∈I₂, the eigenvalues λ and eigenvectors w of the generalized eigenvalue problem:

Z_{1[p]}^{t}BₚZ_{1[p]}w=λZ_{1[p]}^{t}AₚₚZ_{1[p]}w (2)

may be found 603. It is possible to keep only the “relevant” eigenvectors, i.e. the eigenvectors associated with eigenvalues λ below a second predefined threshold θ₂ (i.e. eigenvectors w associated to λ<θ₂). For instance, the second predefined threshold θ₂ may be chosen such that θ₁≥θ₂.

In one embodiment, each relevant eigenvector wₖ^{p} solution of the above problem (2) may be prolonged into a vector xₖ^{p} of the same height than the matrix A_{c} by completing with zero values for the indexes that do not correspond to a received line. Z₂ may then be determined by concatenating said vectors xₖ^{p} according to:
firstly, the respective order value of the subdomain Ω_{2,p} for which the vector xₖ^{p} is determined; and
secondly, the respective eigenvalue of the relevant eigenvector.

The projector Z may then be determined 605 based on the formula Z=Z₁Z₂.

The determination 604 of Z₂ is optional. In one alternative embodiment, for each relevant eigenvector wₖ^{p}, a respective vector vₖ^{p} may be computed according to vₖ^{p}=Z_{1[p]}wₖ^{p}. Then, each selected vector vₖ^{p} may be prolonged into a vector q of the same height than the matrix A, by completing with zero values. The projector Z may then be obtained 605 by concatenating the vectors Vₖ^{p} according to:
firstly, the respective order value of the subdomain Ω_{2,p} for which the vector Vₖ^{p} is determined; and
secondly, the respective eigenvalue of the relevant eigenvector.

The preconditioner M may then be calculated based on the projector Z, for instance according to one of the following formulas:

$${M}^{- 1} = {\sum }_{{Ω}_{1 , i}} {R}_{1 , i}^{t} {A}_{1 , i}^{- 1} {R}_{, 1 , i} + ( {\sum }_{{Ω}_{2 , p}} {R}_{2 , p}^{t} {Z}_{1 [ p ]} {A}_{2 , [ p ]}^{- 1} {Z}_{1 [ p ]}^{t} {R}_{2 , p} ) + {Z}_{1} {{Z}_{2} ( {Z}_{2}^{t} {Z}_{1}^{t} {AZ}_{1} {Z}_{2} )}^{- 1} {Z}_{2}^{t} {Z}_{1}^{t}$$

$$or$$

$${M}^{- 1} = {\sum }_{{Ω}_{1 , i}} {R}_{1 , i}^{t} {A}_{1 , i}^{- 1} {R}_{, 1 , i} + ( {\sum }_{{Ω}_{2 , p}} {R}_{2 , p}^{t} {Z}_{1 [ p ]} {A}_{2 , [ p ]}^{- 1} {Z}_{1 [ p ]}^{t} {R}_{2 , p} ) + {Z ( {Z}^{t} AZ )}^{- 1} {Z}^{t}$$

Of course, other formula linking M and Z may be used.

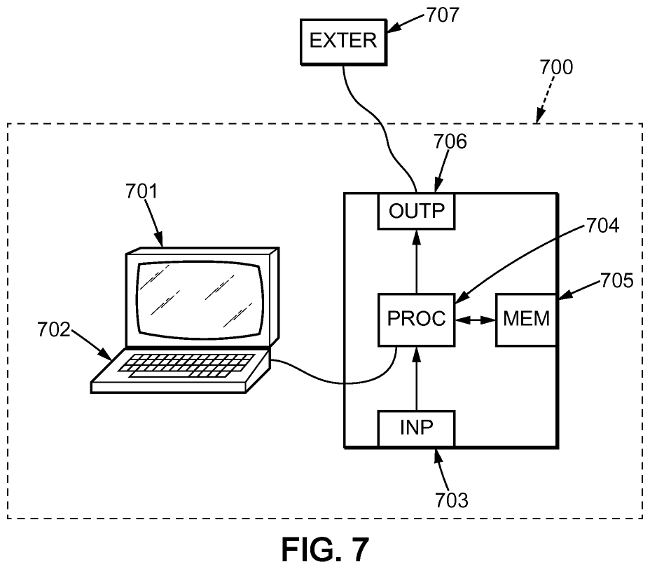

Part of the steps described above can represent steps of an example of a computer program which may be executed by the device of FIG. 7.

FIG. 7 is a possible embodiment for a device that enables the present invention.

In this embodiment, the device 700 comprise a computer, this computer comprising a memory 705 to store program instructions loadable into a circuit and adapted to cause circuit 704 to carry out the steps of the present invention when the program instructions are run by the circuit 704.

The memory 705 may also store data and useful information for carrying the steps of the present invention as described above.

The circuit 704 may be for instance:
a processor or a processing unit adapted to interpret instructions in a computer language, the processor or the processing unit may comprise, may be associated with or be attached to a memory comprising the instructions, or
the association of a processor/processing unit and a memory, the processor or the processing unit adapted to interpret instructions in a computer language, the memory comprising said instructions, or
an electronic card wherein the steps of the invention are described within silicon, or
a programmable electronic chip such as a FPGA chip (for «Field-Programmable Gate Array»).

This computer comprises an input interface 703 for the reception of data used for the above method (e.g. the reservoir model) according to the invention and an output interface 706 for providing the projector Z or the preconditioner M to an external device 707.

To ease the interaction with the computer, a screen 701 and a keyboard 702 may be provided and connected to the computer circuit 704.

It has to be noted that the projector Z associated with the coarse system obtained with the method of the present invention is different from the projector Z that is obtained by applying the method of PCT/IB2017/001566 to the coarse matrix A_{c}. The details of this difference are provided hereinafter.

FIG. 8 is a representation of submatrices corresponding to the p-th subdomain of the coarse partition.

As represented in FIG. 8, let us consider the following notations:
Z_{1[p]} is the bloc-diagonal part of the projector Z₁ corresponding to the subset of subdomains of the fine partition P₁ that compose the p-th subdomain Ω_{2,p} of the coarse partition P₂;
Z_{1[p*]} is the bloc-column part of the projector Z₁ corresponding to the subset of subdomains of the fine partition P₁ that compose the p-th subdomain Ω_{2,p} of the coarse partition P₂;
Aₚₚ^{c} is the diagonal part of the coarse matrix Z_{1[p]}^{t}AZ_{1[p]} corresponding to the p-th subdomain Ω_{2,p};
A_{p*}^{c}, is the block-row part of the coarse matrix Z_{1[p]}^{t}AZ_{1[p]} corresponding to the p-th subdomain Ω_{2,p}.

The generalized eigenvalue problem corresponding to the p-th subdomain Ω_{2,p} in the coarse system is:

Bₚ^{c}v=λAₚₚ^{c}v

We now detail to what correspond the matrices Bₚ^{c} and Aₚₚ^{c} in the case where the method of the prior art (i.e. the method of PCT/IB2017/001566) is used on the one hand, and in the case where the present invention is used on the other hand.

In both cases, Aₚₚ^{c} is the same matrix: Aₚₚ^{c}=Z_{1[p]}^{t}AₚₚZ_{1[p]}.

In PCT/IB2017/001566, it was proposed applying the same method to the coarse system. This leads to construct:

Bₚ^{c}=Aₚₚ^{c}+Diag(Rowsum(A_{p*}^{c})−Rowsum(Aₚₚ^{c}))

where the operator Rowsum(M) is the multiplication of M by a vector which all entries are 1 (dimension of the vector is the number of columns in M), and the operator Diag(v) transforms a vector v into a diagonal matrix D which entries are Dᵢᵢ=vᵢ.

In other words, Bₚ^{c} is obtained by adding row by row to the diagonal of Aₚₚ^{c} the entries of A_{p*}^{c} that are not in Aₚₚ^{c}.

Now, let us consider the eigenvalue problem induced by the “coarse” partition P₂ on the matrix A (i.e. we are using the method of the prior art on the matrix A with the coarse partition P₂). This eigenvalue problem is, for the p-th subdomain Ω_{2,p} of the partition P₂:

Bₚv=λAₚₚv

where Bₚ=Aₚₚ+Dₚ and Dₚ=Diag (Rowsum(A_{p*})−Rowsum(Aₚₚ)).

In the method presented here, the idea is that an optimal manner to construct the part of the projector Z_{c}² corresponding to the p-th subdomain Ω_{2,p} is to project this problem on the coarse level using the projector Z_{1[p]}.

Therefore, we obtain the eigenvalue problem (2) associated with the p-th subdomain Ω_{2,p} and the matrix A_{c}:

Z_{1[p]}^{t}BₚZ_{1[p]}w=λZ_{1[p]}^{t}AₚₚZ_{1[p]}w (2)

Since Aₚₚ^{c}=Z_{1[p]}^{t}AₚₚZ_{1[p]}, we obtain the local eigenvalue problem for p-th subdomain Ω_{2,p} in the coarse matrix A_{c}:

Bₚ^{c}v=λAₚₚ^{c}v

where Bₚ^{c}=BₚZ_{1[p]}.
Hence, with the method presented here,

Bₚ^{c}=Z_{1[p]}^{t}(Aₚₚ+Diag(Rowsum(A_{p*})−Rowsum(A_{cc}))Z_{1[p]}

Since Aₚₚ^{c}=Z_{1[p]}^{t}AₚₚZ_{1[p]}, we finally obtain:

Bₚ^{c}=Aₚₚ^{c}+Z_{1[p]}^{t}(Diag(Rowsum(A_{p*})−Rowsum(A_{cc})))Z_{1[p]}

It is easy to see that this formula is different from the formula obtained for the method of the prior art, at least because the matrix Diag (Rowsum(A_{p*}^{c})−Rowsum(Aₚₚ^{c})) is a (scalar) diagonal matrix whereas the matrix Z_{1[p]}^{t} (Diag (Rowsum(A_{p*})−Rowsum(A_{cc})))Z_{1[p]} is a block diagonal matrix.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

A person skilled in the art will readily appreciate that various parameters disclosed in the description may be modified and that various embodiments disclosed may be combined without departing from the scope of the invention.

It is noted that the previous examples are 2D examples for the sake of simplicity, but 3D examples may be derived from these 2D examples without difficulties.

It is also noted that all the above formula can be rewritten by using the transposition operator. Therefore, even if in the above description, an “index” corresponds to a “row index”, the skilled person would easily understand that an “index” could also correspond to a “column index”.

1. A computer-implemented method for determining hydrocarbon production of a reservoir, wherein the method comprises:
modeling the reservoir with a gridded model comprising a plurality of cells, said gridded model having:
coarse partition, said coarse partition having coarse subdomains,
a fine partition, said fine partition having fine subdomains, each coarse subdomain being composed of a subset of fine subdomains;
determining a first matrix based on a Jacobian matrix function of the gridded model;
wherein each fine subdomain has a respective first order value, said first order value being function of an index of a line in a subset of consecutive lines of the first matrix corresponding to said fine subdomain,
wherein each coarse subdomain has a respective second order value, said second order value being function of an index of a line in a subset of consecutive lines of the first matrix corresponding to said coarse subdomain;
wherein the method further comprises:
splitting the first matrix into subsets of consecutive lines, each subset of consecutive lines corresponding to a respective fine subdomain, each subset of consecutive lines being received by one dedicated processor;
for each subset of consecutive lines:
creating a first respective square matrix based on said subset;
creating a second respective square matrix based on said subset;
determining extended generalized eigenvectors xᵢ and respective eigenvalues λᵢ of the first square matrix and the second square matrix;
determining relevant eigenvectors, the relevant eigenvector being the determined eigenvectors having respective eigenvalues below a first predetermined threshold;
determining a first projector matrix as a concatenation of the relevant eigenvectors ordered according to:
firstly, the respective first order value of the fine subdomain Ω_{1,i} corresponding to the subset of consecutive lines for which the relevant eigenvector is determined; and
secondly, the respective eigenvalue of the relevant eigenvector;
for each coarse subdomain:
extracting a submatrix from the first projector matrix, said submatrix corresponding to a subset of fine subdomains composing said coarse subdomain;
determining generalized eigenvectors of a third square matrix and a fourth square matrix and respective eigenvalues, said third square matrix and fourth square matrix being function of said submatrix;
determining relevant second eigenvectors, the relevant second eigenvectors being the determined eigenvectors of the third square matrix and the fourth square matrix having respective second eigenvalues below a second predetermined threshold;
determining projector matrix based on a concatenation of vectors, each vector being function of a respective relevant second eigenvector, said vectors being ordered according to:
firstly, the second order value of the coarse subdomain for which the respective relevant second eigenvector is determined; and
secondly, the respective eigenvalue of the relevant second eigenvector;
determining a preconditioner operator based on the projector matrix;
determining hydrocarbon production for the reservoir based on the preconditioner operator.

2. The method of claim 1, wherein the determining of the first matrix comprises:
permuting a Jacobian matrix function of the gridded model according to an ordering of unknowns involved in a computation of flow rates in the gridded model, each unknown having a respective index in said permutation, the permutation being performed so that all unknowns related to a same partition among the coarse partition and fine partition have contiguous indexes in the new ordering and so that inside each contiguous set of indexes, the unknowns of cells that are connected have an index greater than the indexes of unknowns of cells that have no connection; and
determining a first matrix based on the permutation of the Jacobian matrix.

3. The method of claim 1, wherein each line of the first matrix belongs to only one subset among the subsets of consecutive lines.

4. The method of claim 1, wherein, for a partition among the fine partition and the coarse partition, the order value of the first subdomain is greater than the order value of the second subdomain if:
a first subdomain of the partition corresponds to a first subset of consecutive lines of the first matrix,
a second subdomain of the partition corresponds to a second subset of consecutive lines of the first matrix, and
the first subset has a line subsequent to a line of the second subset.

5. The method of claim 1, further comprising:
for each determined relevant second eigenvector, determining a respective extended relevant second eigenvector;
wherein the determining the projector matrix i-comprises:
determining a second projector matrix as a concatenation of the extended relevant second eigenvectors ordered according to:
firstly, the second order value of the coarse subdomain for which the respective relevant second eigenvector is determined; and
secondly, the respective eigenvalue of the relevant second eigenvector;
determining the projector matrix based on the first projector matrix and the second projector matrix.

6. The method of claim 5, wherein the projector matrix is a product of the first projector matrix and the second projector matrix.

7. The method of claim 1, further comprising:
for each determined relevant second eigenvector, determining a respective vector as a function of a product of the relevant second eigenvector and the submatrix corresponding to the coarse subdomain for which the respective relevant second eigenvector is determined;
wherein the projector matrix is a concatenation of the determined vector ordered according to:
firstly, the second order value of the coarse subdomain for which the respective relevant second eigenvector is determined; and
secondly, the respective eigenvalue of the relevant second eigenvector.

8. The method of claim 7, wherein each vector is an extended vector derived from a product of the submatrix and the relevant second eigenvector.

9. The method of claim 1, wherein the first predetermined threshold is greater than or equal to the second predetermined threshold.

10. The method of claim 1, wherein the preconditioner operator is function of Z(Z^{t}AZ)⁻¹Z^{t}, Z being the determined projector matrix and A being the first matrix.

11. A non-transitory computer readable storage medium, having stored thereon a computer program comprising program instructions, the computer program being loadable into a data-processing unit and adapted to cause the data-processing unit to carry out the method of claim 1 when the computer program is run by the data-processing device.

12. A device for determining hydrocarbon production for a reservoir, wherein the device comprises an interface configured to receive information of the reservoir, and a first processor configured for:
modeling the reservoir with a gridded model comprising a plurality of cells, said gridded model having:
a coarse partition said coarse partition having coarse subdomains,
a fine partition said fine partition having fine subdomains, each coarse subdomain being composed of a subset of fine subdomains;
determining a first matrix based on a Jacobian matrix function of the gridded model;
wherein each fine subdomain has a respective first order value, said first order value being function of an index of a line in a subset of consecutive lines of the first matrix corresponding to said fine subdomain,
wherein each coarse subdomain has a respective second order value, said second order value being function of an index of a line in a subset of consecutive lines of the first matrix corresponding to said coarse subdomain;
wherein the method further comprises:
splitting the first matrix into subsets of consecutive lines, each subset of consecutive lines corresponding to a respective fine subdomain, each subset of consecutive lines being received by one dedicated processor;
wherein the device further comprises a plurality of processors, each subset of consecutive lines being received by one dedicated processor in said plurality of processors;
wherein, for each subset of consecutive lines, a processor in the plurality of processor is configured for:
creating a first respective square matrix based on said subset;
creating a second respective square matrix based on said subset;
determining extended generalized eigenvectors and respective eigenvalues of the first square matrix and the second square matrix;
determining relevant eigenvectors, the relevant eigenvector being the determined eigenvectors having respective eigenvalues below a first predetermined threshold;
wherein the first processor is further configured for:
determining a first projector matrix as a concatenation of the relevant eigenvectors ordered according to:
firstly, the respective first order value of the fine subdomain corresponding to the subset of consecutive lines for which the relevant eigenvector is determined; and
secondly, the respective eigenvalue of the relevant eigenvector;
for each coarse subdomain, the first processor configured for:
extracting a submatrix from the first projector matrix, said submatrix corresponding to a subset of fine subdomains composing said coarse subdomain;
determining generalized eigenvectors of a third square matrix and a fourth square matrix and respective eigenvalues, said third square matrix and fourth square matrix being function of said submatrix;
determining relevant second eigenvectors, the relevant second eigenvectors being the determined eigenvectors of the third square matrix and the fourth square matrix having respective second eigenvalues below a second predetermined threshold;
determining a projector matrix based on a concatenation of vectors, each vector being function of a respective relevant second eigenvector, said vectors being ordered according to:
firstly, the second order value of the coarse subdomain for which the respective relevant second eigenvector is determined; and
secondly, the respective eigenvalue of the relevant second eigenvector;
determining a preconditioner operator based on the projector matrix; and
determining hydrocarbon production for the reservoir based on the preconditioner operator.
